(19) United States
(12) Patent Application Publication
(10) Pub. No.: US 2009/0129514 A1
(43) Pub. Date: May 21, 2009

(54) Accurate data-aided frequency tracking circuit

(75) Inventor: Moshe Twitto, Givat Shmuel (IL)

Correspondence Address: MARTIN D. MOYNIHAN d/b/a PRTSI, INC., P.O. BOX 16446, ARLINGTON, VA, 22215, US

(73) Assignee: Horizon Semiconductors Ltd., Herzlia (IL)

(21) Appl. No.: 11/984,494

(22) Filed: Nov. 19, 2007

(51) Int. Cl. H04L 7/02; H03D 1/00; H04L 27/06

(52) U.S. Cl. 375/341; 375/359; 375/373; 375/344

(57) ABSTRACT

A frequency compensation circuit for compensating for a frequency offset in a received signal, the received signal including a periodically repeated pilot sequence for phase locking. The circuit comprises a phase estimator for estimating a phase of the received signal; a phase compensator, associated with the phase estimator, for compensating for the phase; a frequency estimator, comprising a maximum likelihood estimator comprising a first modification for estimating a frequency offset which is small relative to a symbol time, from the pilot sequence, the frequency estimator being connected downstream of the phase compensator; and a frequency compensator for applying a compensation to the signal, thereby to compensate for the frequency offset. The compensator is suitable for the exacting conditions of the DVB-S2 standard.

### FIELD AND BACKGROUND OF THE INVENTION

The present invention, in some embodiments thereof, relates to an improved data-aided frequency tracking circuit and, more particularly, but not exclusively, to such circuits which use maximum likelihood estimations and a regularly repeated pilot signal for the frequency tracking. That is to say, the present invention is generally related to a carrier frequency estimation circuit for a digital demodulator operating on passband, digitally modulated signals, and a method of estimating the carrier frequency of the received data. More specifically, the present invention relates to carrier frequency estimation when known data is embedded in the transmitted signal.

The purpose of digital communication is to deliver discreet data streams from one point to others. In order to achieve this purpose, a large variety of modulation methods have been developed over the years. Those methods can be conceptually divided into two categories: Baseband and Passband communications. Modulation methods which belong to the first category generally modulate the amplitude of a data-carrying pulse and transmit a sequence of such modulated pulses directly over some sort of wire (e.g., twisted pair). However, in order to be able to transmit data wirelessly, passband methods have been introduced. Moreover, even in wired systems, frequency multiplexing of different sources necessitates passband modulation techniques. In passband communication, the modulated data is frequency-translated into some frequency band, and then amplified and transmitted. In the process of frequency shifting, the bandwidth of the transmitted signal may be doubled as compared to the bandwidth of the original, baseband signal. The extra bandwidth can be exploited by using the quadrature portion of the transmitted signal, hence also doubling the data rate. Examples of such modulation methods are quadrature amplitude modulation (QAM) and phase shift keying (PSK). In baseband representation, the discreet data can be seen as stream of complex value symbols which multiply a data-carrying pulse. In mathematical form, the stream of symbols can be formulated as follows:

$$x ( t ) = {\sum }_{n} {a}_{n} g ( t - nT ) , \qquad ( 1 )$$

where {aₙ} is a sequence of complex data symbols, g(t) is the data-carrying pulse, and T is a symbol period. It is very common for g(t) to be a square root raised-cosine (SRRC) pulse, which is a perfectly band-limited pulse. The SRRC thus has the desired property that, after matched-filtering, the resulting pulse does not introduce inter-symbol interference (ISI). After frequency translation, the passband signal may be put in the following form:

y(t)=real{x(t)·e^{j2πf}^{ₑ}^{t}}, (2)

where f_{c} is the carrier frequency and j=\sqrt{−1}.

In order to properly demodulate and decode the data in the passband signal (2), the received signal may be downconverted to baseband, as in (1). Mathematically, such downconverting is achieved by multiplying the received signal (2) by e^{-j2πf}^{_{c}}^{t}, and convolving the result with an impulse response of an appropriate low-pass filter.

In practice, the process of down-converting is usually done in several stages. For example, in the digital video broadcasting standard for satellite DVB-S, f_{c} is in the Ku band (generally between 10.7 GHz and 12.75 GHz). Firstly, a wide block of channels is downconverted to an intermediate frequency of usually 950 MHz to 1450 MHz, using the superheterodyne principle, and amplified. This is done by a component called “Low-Noise Block” (LNB), which is generally located on or in the satellite dish. Then, the relatively low frequency signal may be carried over a coaxial cable to the set-top box. There, a tuner selects the desired carrier, and completes the downcoverting process to produce a baseband signal. Since the signal (1) is complex-valued, the tuner generally has two outputs, one for the real part of the signal and the other for the imaginary part.

Now, in real world conditions, the baseband signal from the tuner is not located precisely around zero frequency, but in some other near-DC frequency. This frequency error, or offset, is due to inaccuracies in the LNB as well as the tuner, whose oscillators are not matched exactly to one another or for that matter to the transmitter's oscillator. In the above example, the frequency offset can be as large as ±5 MHz. Clearly, this frequency offset has to be compensated in the receiver. The outputs of the tuner are fed into an analog to digital converter (ADC), which sample the signal. The ADC sampling frequency may or may be not locked to the received signal's symbol rate. If the sampling frequency is locked to the received signal's symbol frequency, the sampling frequency may be as low as the symbols rate. If, on the other hand, it is not locked to the symbols rate, the sampling frequency needs to satisfy Nyquist's sampling theorem, i.e., it should be at least twice the desired signal's bandwidth. Usually, the sampling frequency is taken to be at least twice the symbol's rate. Within such receivers, the timing recovery is done digitally, by means of a digital interpolator.

The essential tasks of a receiver include automatic gain control (AGC), carrier frequency estimation and compensation, timing recovery, matched filtering/equalization and phase estimation and compensation. Some of the above tasks, can not be done properly if a substantial frequency offset is present. For example, the performance of the well-known Gardner algorithm for timing recovery is degraded rapidly as the frequency offset exceeds 20% of the symbols' rate. Likewise, the signal to noise ratio (SNR) at the output of the matched filter also decreases considerably when the frequency offset is above 10% of the symbols' rate. Hence, a way to estimate and compensate the frequency offset at an early stage, preferably directly after the ADC, is crucial to the performance of a digital demodulator. Such frequency compensation is referred to as coarse frequency compensation, since some non-ignorable frequency offset prevails after that process. In some cases, that residual frequency offset can be tracked down effectively by an ordinary second-order type II phase locked loop (PLL), so there is no need to provide another frequency estimation stage. However, there are coded communication systems where the data can be decoded successfully at extremely low signal to noise ratios (SNR). An example of such system is the new satellite digital television standard—DVB-S2. According to that standard, data can be decoded at SNRs down to −2.35 dB. Such high noise power dictates very low PLL bandwidth in order to operate satisfactory, which considerably limits the frequency deviation that can be tracked down by the PLL. Moreover, the frequency offset is not constant; rather, it changes over time. Referring to the DVB-S2 standard, the slew-rate of the carrier frequency which is to be tracked by the receiver is as much as 30 kHz/sec. Combining the extremely low SNR condition with the rapid frequency slew rate, we obtain a communication system which necessitates some sort of fine frequency tracking mechanism.

In order to ease the implementation of receivers, communication standards insert known data sequences in a predetermined periodicity. Those known sequences, or pilot sequences, can be exploited to produce fine frequency estimations at regular spacing, which enables quasi-continuous frequency tracking. There are several known methods of tracking the pilot sequences, each with its own estimation error variance and computational burden. Most of them are based on a maximum-likelihood (ML) approach. An exact ML estimator requires finding the peak of a periodogram. Since accurate computation of the ML estimator is very complicated, approximations are often used. One of the best estimators of the approximation family is the estimator proposed by Zakharov et al. Other estimators are obtained using different high SNR approximation to the ML estimator. Some important examples are L&R estimator, the Generalized-Kay estimator and Fits estimator.

All of the abovementioned frequency estimators, as well as many others rely on the likelihood function:

$$Λ ( f , θ ) = Re \{ {\sum }_{n = 0}^{N - 1} {r}_{n} \cdot {e}^{- j ( 2 π fnT + θ )} \} \qquad ( 1 )$$

which is a monotonic function of the conditional probability of receiving the sequence {r₀, r₁, . . . , r_{N-1}}, given that the frequency deviation is f and the phase offset is θ. It is also assumed that the additive noise is Gaussian and white, and that the modulation has been removed from the received data, since the transmitted sequence is known a-priori. Finding the pair (\hat{f},\hat{θ}) which maximizes Eq. (1) provides the best unbiased joint estimator of f and θ. The two-dimensional maximization problem can be expressed as:

$$Λ ( f , θ ) = \vert {\sum }_{n = 0}^{N - 1} {r}_{n} \cdot {e}^{- j 2 π fnT} \vert cos ( θ - arg ( λ ) ) , \qquad ( 2 )$$

Where λ is the expression inside the bars in (2). From (2) it is clear that one can find \hat{f} that maximizes (2) simply by maximizing the following one-dimensional likelihood function:

$$\tilde{Λ} ( f ) = \vert {\sum }_{n = 0}^{N - 1} {r}_{n} \cdot {e}^{- j 2 π fnT} \vert . \qquad ( 3 )$$

The value of \hat{θ} which maximizes (2) is simply \hat{σ}=arg(λ).

The very low PLL bandwidth available in the above referred to DVB-S2 standard prohibits large estimation errors altogether, since such errors drive the PLL out of lock. The narrower the PLL's bandwidth the smaller the allowed error-range is. Thus it is an essential need that the error variance be as small as possible.

### SUMMARY OF THE INVENTION

The present invention provides maximum likelihood estimation of the frequency offset to a signal which has already been compensated for phase offset. More particularly but not exclusively, a modified maximum likelihood estimation of frequency offset is provided for the specific case of a phase compensated signal where the frequency offset is considerably lower than the symbol time.

According to an aspect of some embodiments of the present invention there is provided a frequency compensation circuit for compensating for a frequency offset in a received signal, the received signal including a periodically repeated pilot sequence for phase locking, the circuit comprising:

a phase estimator for estimating a phase offset of said received signal;

a phase compensator, associated with said phase estimator, for compensating for said phase offset;

a maximum likelihood frequency estimator, the frequency estimator being connected downstream of said phase compensator, the maximum likelihood estimator being configured to provide maximum likelihood estimation of a frequency offset in said received signal using said pilot sequence in a phase compensated version of said received signal; and

a frequency compensator, associated with said frequency estimator, for applying a compensation to said signal, thereby to compensate for said frequency offset.

In an embodiment, said maximum likelihood frequency estimator comprises a first modification for estimating the frequency offset under the assumption that the frequency offset is small relative to a symbol time.

An embodiment further comprises a coarse frequency estimator connected upstream of said phase compensator and configured to obtain a course estimation of said frequency offset.

In an embodiment, said maximum likelihood estimator comprises a second modification for estimating a frequency offset of a phase compensated signal.

In an embodiment, said received signal comprises n complex symbols, and said compensation circuit comprises a separator for separating said n complex symbols into n real symbols Xn and n imaginary symbols Yn.

In an embodiment, said maximum likelihood estimator is configured to compute a frequency offset from:

$$\hat{f} = \frac{\frac{1}{π} \sum {X}_{n} {n}^{2} - \sqrt{{( \frac{1}{π} \sum {X}_{n} {n}^{2} )}^{2} - \frac{2}{{π}^{2}} ( \sum {Y}_{n} n ) ( \sum {Y}_{n} {n}^{3} )}}{2 \cdot \sum {Y}_{n} {n}^{3}}$$

In an embodiment, said maximum likelihood estimator comprises a counter, a series of multipliers and accumulators, and a series of paths defined from real and imaginary outputs of said separator and from said counter, through said multipliers and accumulators, to accumulate summations for said maximum likelihood estimation, each path defining a different summation.

In an embodiment, said frequency compensation comprises feedback compensation via a feedback loop, the feedback loop comprising a numerically controlled oscillator.

An embodiment may comprise an averager, adapted to perform averaging of frequency offsets over a series of pilot signals.

According to a second aspect of the present invention there is provided a frequency compensation method for compensating for a frequency offset in a received signal, the received signal including a periodically repeated pilot sequence for phase locking, the method comprising:

estimating a phase of said received signal;

compensating for said phase;

estimating a maximum likelihood frequency offset of the received signal using the pilot sequence from within said phase compensated signal; and

applying a frequency compensation to said received signal, thereby to compensate for said frequency offset.

In an embodiment, said maximum likelihood frequency offset estimating comprises using a first modification of said maximum likelihood estimation wherein said first modification is based on an assumption that said frequency offset is small relative to a symbol time,

An embodiment comprises carrying out coarse frequency estimation of said frequency offset prior to said phase compensation.

In an embodiment, said maximum likelihood estimating further comprises a second modification for estimating a frequency offset of a phase compensated signal.

In an embodiment, said received signal comprises n complex symbols, and said method comprises separating said n complex symbols into n real symbols Xn and n imaginary symbols Yn prior to said maximum likelihood estimation.

In an embodiment, said maximum likelihood estimating comprises computing a frequency offset from:

$$\hat{f} = \frac{\frac{1}{π} \sum {X}_{n} {n}^{2} - \sqrt{{( \frac{1}{π} \sum {X}_{n} {n}^{2} )}^{2} - \frac{2}{{π}^{2}} ( \sum {Y}_{n} n ) ( \sum {Y}_{n} {n}^{3} )}}{2 \cdot \sum {Y}_{n} {n}^{3}}$$

In an embodiment, said calculating comprises accumulating summations for said maximum likelihood estimation via multiplications, each path defining a different summation.

In an embodiment, said frequency compensation comprises feedback compensation via a feedback loop.

An embodiment comprises averaging of frequency offsets over a series of pilot signals.

According to a third aspect of the present invention there is provided a preparation circuit for providing summations to a maximum likelihood estimator, comprising:

a separator for separating a complex incoming signal into a real part at a real output and an imaginary part at an imaginary output,

a counter for providing an ongoing symbol count over a period of the pilot sequence,

a plurality of multipliers,

a plurality of accumulators, and

a series of paths each connecting one of said outputs, said counter, at least one of said multipliers and one of said accumulators, such that each path of said series defines a different summation for said maximum likelihood estimation.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

Implementation of the method and/or system of embodiments of the invention can involve performing or completing selected tasks manually, automatically, or a combination thereof. Moreover, according to actual instrumentation and equipment of embodiments of the method and/or system of the invention, several selected tasks could be implemented by hardware, by software or by firmware or by a combination thereof using an operating system.

For example, hardware for performing selected tasks according to embodiments of the invention could be implemented as a chip or a circuit. As software, selected tasks according to embodiments of the invention could be implemented as a plurality of software instructions being executed by a computer using any suitable operating system. In an exemplary embodiment of the invention, one or more tasks according to exemplary embodiments of method and/or system as described herein are performed by a data processor, such as a computing platform for executing a plurality of instructions. Optionally, the data processor includes a volitile memory for storing instructions and/or data and/or a non-volatile storage, for example, a magnetic hard-disk and/or removable media, for storing instructions and/or data. Optionally, a network connection is provided as well. A display and/or a user input device such as a keyboard or mouse are optionally provided as well.

### BRIEF DESCRIPTION OF THE DRAWINGS

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1 is a simplified schematic diagram of the frequency compensation circuitry according to one embodiment of the present invention.

FIG. 2 is a simplified diagram of the frequency offset estimation unit of FIG. 1;

FIG. 3 is a prior art feedforward frequency compensation system, that can usefully be adopted in embodiments of the present invention.

FIG. 4 is a simplified flow chart illustrating the process of frequency estimation according to a preferred embodiment of the present invention.

### DESCRIPTION OF EMBODIMENTS OF THE INVENTION

Preferred embodiments of the present invention relate principally to a situation in which the frequency offset at the input to a phase locked loop (PLL) is relatively small, say of the order of 10⁻³ of the symbol rate. While prior art systems adopt various methods and approximations to maximize \tilde{Λ}(f), the present embodiments take a different approach.

The above-mentioned offset, while small, is still large enough to overwhelm the PLL. In such a case one may first estimate and compensate for the phase of the signal. The resulting phase compensated signal may be passed through a modified maximum likelihood estimator to provide an estimate of the frequency offset. The estimation procedure above yields a biased estimator. The modified maximum likelihood estimator is based on an approximation valid when the frequency offset is small relative to the symbol rate, which is the situation described above. A derivation is provided below.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

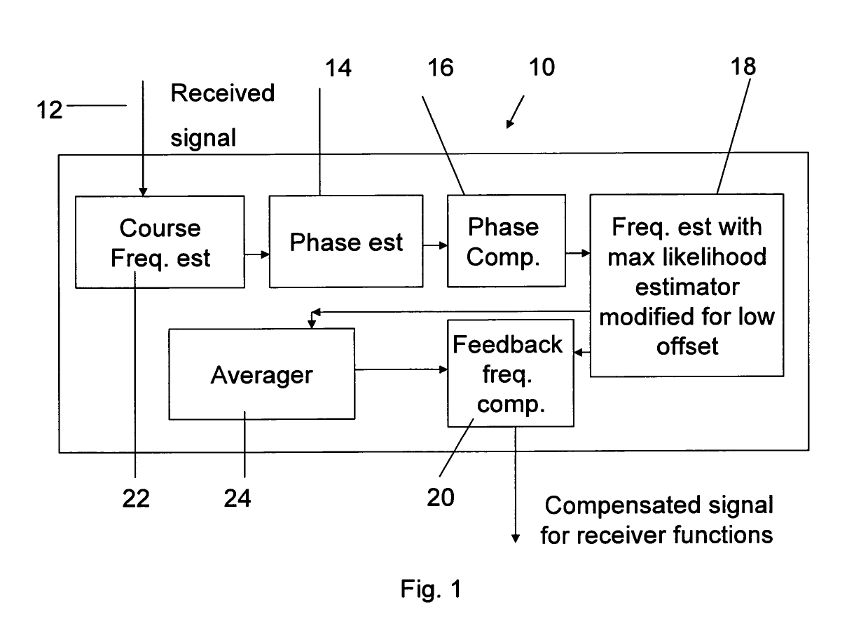

Referring now to the drawings, FIG. 1 illustrates a frequency compensation circuit 10 for compensating for a frequency offset in a received signal 12. The received signal 12 includes a periodically repeated pilot sequence which is meant for phase locking.

The circuit includes a phase estimator 14 for estimating a phase of the received signal. A phase compensator 16 lies at the output of the phase estimator, and provides phase compensation based on the phase estimation, to produce a phase compensated signal at its output. As will be explained below, the phase compensation allows for simplification of the maximum likelihood function.

A frequency estimator 18 includes a maximum likelihood estimator designed to work with the pilot sequence. The maximum likelihood estimator includes a first modification which is specifically for estimating a frequency offset which is small relative to a symbol time, from the pilot sequence. As will be explained below the modification is an approximation to the maximum likelihood estimator which is true for such small offsets.

The maximum likelihood estimator may further comprise a second modification for estimating a frequency offset of a phase compensated signal. The two modifications may be combined to provide a maximum likelihood estimation based on separate summations of the real and imaginary parts of the input signal.

As shown, the frequency estimator is connected downstream of the phase compensator.

A frequency compensator 20 is connected downstream of the estimator and applies a compensation to the signal based on the estimate. The result is a compensated signal from which the standard receiver functions can operate.

The circuit 10 may also include a coarse frequency estimator upstream of the phase compensator.

The received signal includes a pilot sequence which comprises n complex symbols. The frequency estimator may include a separator for separating the n complex symbols into n real symbols Xn and n imaginary symbols Yn for separate consideration in the estimator.

As will be derived below, the modified estimator may compute the maximum likelihood frequency offset from:

$$\hat{f} = \frac{\frac{1}{π} \sum {X}_{n} {n}^{2} - \sqrt{{( \frac{1}{π} \sum {X}_{n} {n}^{2} )}^{2} - \frac{2}{{π}^{2}} ( \sum {Y}_{n} n ) ( \sum {Y}_{n} {n}^{3} )}}{2 \cdot \sum {Y}_{n} {n}^{3}}$$

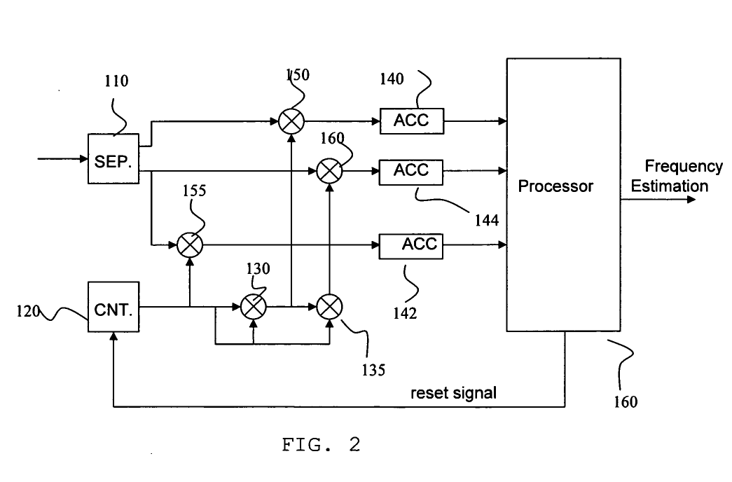

As shown in FIG. 2, the maximum likelihood estimator comprises a counter, a series of multipliers and accumulators. A series of paths from real and imaginary outputs of the separator and from the counter is defined through the multipliers and accumulators, to accumulate summations for the maximum likelihood estimation, so that each path defines a different summation in the above equation.

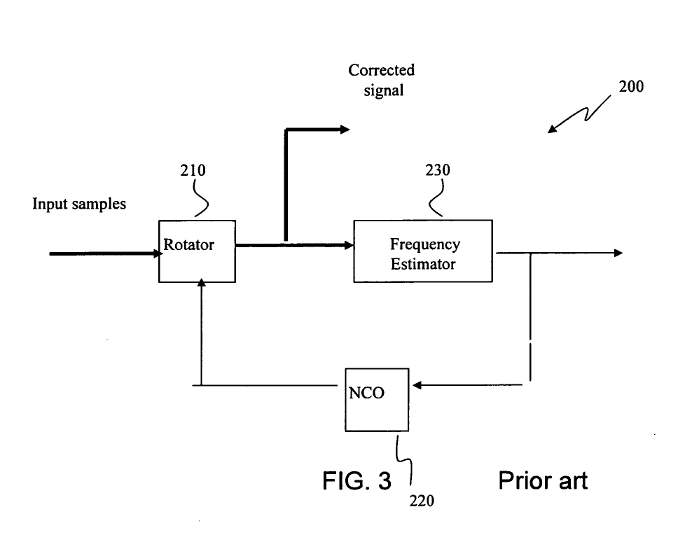

The frequency compensation unit 20 may provide feedback compensation via a feedback loop. As shown in FIG. 3, the feedback loop comprises a numerically controlled oscillator.

An averager, 24, may average the frequency offsets over a series of pilot signals to provide a more accurate estimate, based on the principle that the frequency offset only changes slowly.

As stated above, there are many practical situations where the residual frequency offset at the input of the PLL is relatively small, say in the order of 10⁻³ of the symbols rate. In such cases, according to the present embodiment, one may first estimate the phase at the signal input. It is noted that the signal phase is almost constant over a few tens of symbols. Then compensate for the phase, and then estimate the frequency offset, using the modified likelihood function to be derived below.

The estimation procedure yields a biased estimator. It is appreciated by those skilled in the art, that biased estimators may be uniformly better than their unbiased counterparts. Simulation results show that when the initial frequency offset is sufficiently small, although still too large for the PLL to accommodate by itself, the present algorithm is superior to the conventional ones.

Now, assuming that the initial phase offset is compensated completely, the resulting likelihood function may be expressed as:

$$Λ ( f ) = Re \{ {\sum }_{n = 0}^{N - 1} {r}_{n} \cdot {e}^{- j2π fnT} \} . \qquad ( 4 )$$

In order to find the value of \hat{f} which maximizes (4), we differentiate (4) w.r.t. f, and equate the result to zero, which yields the following optimization equation:

$$Im \{ {\sum }_{n = 0}^{N - 1} {nr}_{n} \cdot {e}^{- j2π fnT} \} . \qquad ( 5 )$$

Since ΔfT<<1, we use the following approximation:

$${e}^{- j2π fnT} \approx \frac{1 - {( 2 π fn )}^{2}}{2} - j2π fnT . \qquad ( 6 )$$

Substituting (6) into (5) and after some straightforward algebra, we obtain the following frequency estimator

$$\hat{f} = \frac{\frac{1}{π} \sum {X}_{n} {n}^{2} - \sqrt{{( \frac{1}{π} \sum {X}_{n} {n}^{2} )}^{2} - \frac{2}{{π}^{2}} ( \sum {Y}_{n} n ) ( \sum {Y}_{n} {n}^{3} )}}{2 \cdot \sum {Y}_{n} {n}^{3}}$$

$$where$$

$${X}_{n} = Re \{ {r}_{n} \}$$

$${Y}_{n} = Im \{ {r}_{n} \} .$$

Although estimator (7) looks very complicated to compute, one may keep in mind that the known (or pilot) signals are spaced in time. For example, in DVB-S2, the pilot signal, which is 36 symbols long, is transmitted every 1440 symbols. Hence there is usually enough time between pilots to compute equation (7) above using firmware techniques, which save hardware size considerably.

According to one embodiment of the present invention, also described schematically in FIG. 2, relatively simple hardware circuitry is used to produce the basic summations. The summations are then fed to and used by a processor 160 to calculate the estimation from equation (7).

FIG. 2 illustrates separator 110 which separates a complex input symbol into real and imaginary parts. A counter 120 keeps a count of the pilot symbols in a specific pilot sequence and a series of paths connect the real and imaginary outputs and the counter via multipliers 130, 135, 150, 155, and 160, to accumulators 140, 142 and 144 to form the different summations in equation 7. In the present case there are three different summations and thus three different paths to three different accumulators. The outputs of the accumulators go to the processor which calculates the overall estimate and provides the estimate of the frequency offset.

In greater detail, input samples are separated into their constituent real and imaginary components by means of the two outputs of separator unit 110. General counter 120 produces sequential numbers, which are raised to the second and third powers by multipliers 130 and 135, respectively. Multiplier 150 multiplies the output of multiplier 130 with the real component at the output of 110. The result is accumulated over the length of the pilot sequence by accumulator 140, which produces ΣXₙn². Likewise, Multipliers 155 and 160 multiply the imaginary part of the input samples by the output of counter 120 and multiplier 135, respectively. Accumulators 142 and 144 produce ΣYₙn and ΣYₙn³, respectively. Processor 160 takes those quantities, and computes (7), which completes the estimation process. After the last symbol in a pilot sequence is processed according to the above, the counter may be set back to zero.

Returning to the initial phase estimation in phase estimator 14 of FIG. 1, a useful function is an ML estimation of the form:

\hat{θ}=arg(Σrₙ) (8)

where arg(x) is the angle of x in polar representation.

Reference is now made to FIG. 3, which is a simplified block diagram which illustrates how frequency compensation may be organized around the frequency estimator 230. It is desirable to keep the residual frequency offset small during tracking, and this may be achieved according to the preferred embodiment by compensating the estimated frequency in a feedback manner. As described in FIG. 3, the input samples are fed into a rotator 210 which rotates a complex number by the angle output from numerically controlled oscillator (NCO) 220. The samples at the output of 210 are passed through frequency estimation block 230 which performs frequency estimation according to the preferred embodiment, based on the pilot signals as explained. The frequency estimation is fed back through NCO 220 which completes the loop.

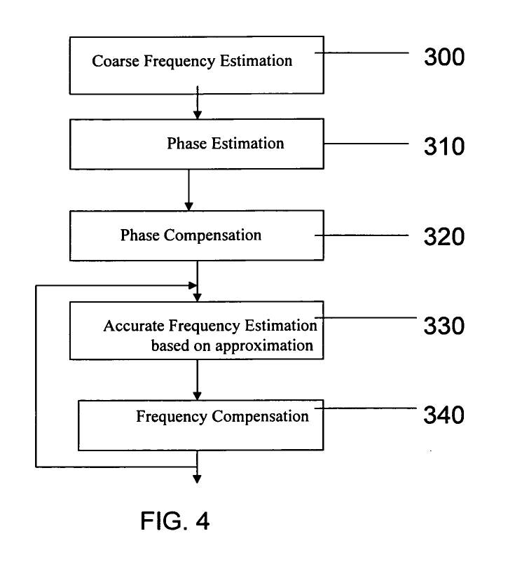

Reference is now made to FIG. 4, which is a simplified flow chart illustrating accurate frequency tracking according to the preferred embodiment. In a first stage 300, a coarse frequency estimation process is conducted, which leaves a relatively small frequency offset. Then, an initial phase estimation is carried out based on equation (8) or any other reliable technique in stage 310. Then in stage 320 the estimated phase may be compensated. After the initial phase is compensated, then in stage 330 the value of f which satisfies equation (5) may be found, using the approximated estimator (7). The estimated frequency may then be compensated using a feedback scheme such as that in FIG. 3.

Returning to FIG. 1, and averager 24 allows time-averaging over multiple pilot signals, to produce a more accurate estimation. It is assumed that the carrier frequency changes slowly relative to the pilots' interval. In that embodiment, N estimations, each based on equation (7) are summed up, and the result is divided by N. The averaged estimation is then used to compensate the frequency offset. Usually N is chosen to be some power of 2, so that the division is reduced to a straightforward shift operation.

The frequency estimator according to the present embodiments may provide enhanced error performance, and thus is suitable for frequency tracking in many kinds of communication systems.

It is expected that during the life of a patent maturing from this application many relevant filters, maximizers and estimators will be developed and the scopes of the corresponding terms are intended to include all such new technologies a priori.

The terms “comprises”, “comprising”, “includes”, “including”, “having” and their conjugates mean “including but not limited to”. This term encompasses the terms “consisting of” and “consisting essentially of”.

As used herein, the singular form “a”, “an” and “the” include plural references unless the context clearly dictates otherwise.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention. To the extent that section headings are used, they should not be construed as necessarily limiting.

What is claimed is:

1. A frequency compensation circuit for compensating for a frequency offset in a received signal, the received signal including a periodically repeated pilot sequence for phase locking, the circuit comprising:
a phase estimator for estimating a phase offset of said received signal;
a phase compensator, associated with said phase estimator, for compensating for said phase offset;
a maximum likelihood frequency estimator, the frequency estimator being connected downstream of said phase compensator, the maximum likelihood estimator being configured to provide maximum likelihood estimation of a frequency offset in said received signal using said pilot sequence in a phase compensated version of said received signal; and
a frequency compensator, associated with said frequency estimator, for applying a compensation to said signal, thereby to compensate for said frequency offset.

2. The frequency compensation circuit of claim 1, wherein said maximum likelihood frequency estimator comprises a first modification for estimating the frequency offset under the assumption that the frequency offset is small relative to a symbol time.

3. The frequency compensation circuit of claim 1, further comprising a coarse frequency estimator connected upstream of said phase compensator and configured to obtain a course estimation of said frequency offset.

4. The frequency compensation circuit of claim 1, wherein said maximum likelihood estimator comprises a second modification for estimating a frequency offset of a phase compensated signal.

5. The frequency compensation circuit of claim 4, wherein said received signal comprises n complex symbols, and said compensation circuit comprises a separator for separating said n complex symbols into n real symbols Xn and n imaginary symbols Yn.

6. The frequency compensation circuit of claim 5, wherein said maximum likelihood estimator is configured to compute a frequency offset from:
$$\hat{f} = \frac{\frac{1}{π} \sum {X}_{n} {n}^{2} - \sqrt{{( \frac{1}{π} \sum {X}_{n} {n}^{2} )}^{2} - \frac{2}{{π}^{2}} ( \sum {Y}_{n} n ) ( \sum {Y}_{n} {n}^{3} )}}{2 \cdot \sum {Y}_{n} {n}^{3}}$$

7. The apparatus of claim 6, wherein said maximum likelihood estimator comprises a counter, a series of multipliers and accumulators, and a series of paths defined from real and imaginary outputs of said separator and from said counter, through said multipliers and accumulators, to accumulate summations for said maximum likelihood estimation, each path defining a different summation.

8. The apparatus of claim 1, wherein said frequency compensation comprises feedback compensation via a feedback loop, the feedback loop comprising a numerically controlled oscillator.

9. The apparatus of claim 1, further comprising an averager, adapted to perform averaging of frequency offsets over a series of pilot signals.

10. A frequency compensation method for compensating for a frequency offset in a received signal, the received signal including a periodically repeated pilot sequence for phase locking, the method comprising:
estimating a phase of said received signal;
compensating for said phase;
estimating a maximum likelihood frequency offset of the received signal using the pilot sequence from within said phase compensated signal; and
applying a frequency compensation to said received signal, thereby to compensate for said frequency offset.

11. The method of claim 10, wherein said maximum likelihood frequency offset estimating comprises using a first modification of said maximum likelihood estimation wherein said first modification is based on an assumption that said frequency offset is small relative to a symbol time.

12. The method of claim 10, further comprising carrying out coarse frequency estimation of said frequency offset prior to said phase compensation.

13. The method of claim 11, wherein said maximum likelihood estimating further comprises a second modification for estimating a frequency offset of a phase compensated signal.

14. The method of claim 13, wherein said received signal comprises n complex symbols, and said method comprises separating said n complex symbols into n real symbols Xn and n imaginary symbols Yn prior to said maximum likelihood estimation.

15. The method of claim 14, wherein said maximum likelihood estimating comprises computing a frequency offset from:
$$\hat{f} = \frac{\frac{1}{π} \sum {X}_{n} {n}^{2} - \sqrt{{( \frac{1}{π} \sum {X}_{n} {n}^{2} )}^{2} - \frac{2}{{π}^{2}} ( \sum {Y}_{n} n ) ( \sum {Y}_{n} {n}^{3} )}}{2 \cdot \sum {Y}_{n} {n}^{3}}$$

16. The method of claim 15, wherein said calculating comprises accumulating summations for said maximum likelihood estimation via multiplications, each path defining a different summation.

17. The method of claim 10, wherein said frequency compensation comprises feedback compensation via a feedback loop.

18. The method of claim 10, further comprising averaging of frequency offsets over a series of pilot signals.

19. A preparation circuit for providing summations to a maximum likelihood estimator, comprising:
a separator for separating a complex incoming signal into a real part at a real output and an imaginary part at an imaginary output,
a counter for providing an ongoing symbol count,
a plurality of multipliers,
a plurality of accumulators, and
a series of paths each connecting one of said outputs, said counter, at least one of said multipliers and one of said accumulators, such that each path of said series defines a different summation for said maximum likelihood estimation.
